(19) United States
(12) Patent Application Publication
(10) Pub. No.: US 2010/0194379 A1
(43) Pub. Date: Aug. 5, 2010

(54) OPTICAL FIBER ELECTRIC CURRENT MEASUREMENT APPARATUS AND ELECTRIC CURRENT MEASUREMENT METHOD

(76) Inventor: Kiyoshi Kurosawa, Tokyo (JP)

Correspondence Address: KNOBBE MARTENS OLSON & BEAR LLP, 2040 MAIN STREET, FOURTEENTH FLOOR, IRVINE, CA, 92614, US

(21) Appl. No.: 12/677,489

(22) PCT Filed: Apr. 24, 2008
(86) PCT No.: PCT/JP2008/057967

§ 371 Date: Mar. 10, 2010

(30) Foreign Application Priority Data
Sep. 10, 2007 (JP) 2007-234542

(51) Int. Cl. G01R 15/24; G01R 19/00

(52) U.S. Cl. 324/96

(57) ABSTRACT

In a reflection type optical fiber electric current measurement apparatus, a standardization reference signal (Xr), which is defined by the intensity (Pr) of the optical reference signal transmitted through a partial transmission mirror by using a reflector (111B) provided in one end of a sensor fiber as the partial transmission mirror, is subtracted from a standardization detection signal (Xs), which is defined by the intensity (Ps) of the optical detection signal obtained from the light reflected at the partial transmission mirror. Thereby, it is possible to remove noise caused by fluctuation in the polarization state (B) as well as fluctuation in the luminescence intensity (A) of the light source.

### TECHNICAL FIELD

The present invention relates to an electric current measurement method and an electric current measurement apparatus using an optical fiber.

Priority is claimed on Japanese Patent Application No. 2007-234542, filed on Sep. 10, 2007, the contents of which are incorporated herein by reference.

### BACKGROUND ART

Apparatuses using optical sensors are being focused on as electric current or voltage measurement apparatuses. An example of an optical sensor includes a high accuracy sensor such as a so-called optical heterodyne type sensor which uses a photoelectric detector to receive and detect interference generated by mixing an optical signal modulated by a measurement target with a local oscillation signal having a frequency different from the optical signal. (e.g., refer to Non-patent Document 1).

However, this type of sensor is complicated in structure. For this reason, recently, a method or apparatus of detecting an electric current or voltage by converting the Faraday effect or the Pockels effect, which is the detection principle of the optical sensor, into light intensity modulation has been developed and made commercially available.

For example, a method or apparatus is known in the related art for measuring an electric current using a principle of the Faraday effect whereby a polarization plane of linearly-polarized light propagating through a sensor fiber is rotated due to magnetic fields caused by the current I flowing through a conductive material as a measurement target. More specifically, in an electric current measurement apparatus using an optical fiber (hereinafter, referred to as an optical fiber electric current measurement apparatus), the electric current is measured using the Faraday effect whereby a polarization plane of light propagating through a magnetic medium is rotated in proportion to the magnitude of the magnetic field in a propagation direction thereof. The optical fiber is also a sort of magnetic medium. If the linearly-polarized light is incident to the optical fiber which is used as a sensor, and the optical fiber is placed near a conductive material through which a measurement current is flowing (i.e., a magnetic field source), then rotation (Faraday rotation) is generated in the polarization plane of the linearly-polarized light within the optical fiber due to the Faraday effect. At this moment, since magnetic fields are generated in proportion to the current, the rotation angle (Faraday rotation angle) of the polarization plane caused by the Faraday effect is proportional to the magnitude of the measurement current. In this regard, the magnitude of the current can be obtained by measuring the Faraday rotation angle. This is a principle of the optical fiber electric current measurement apparatus.

A method of measuring an electric current using the Faraday effect is advantageous in that it is not affected by electromagnetic noise. Therefore, the method of measuring an electric current using the Faraday effect is very suitably used in electric current measurement in high-voltage equipment such as electric substation equipment or electric transmission equipment.

The optical fiber electric current measurement apparatuses are generally classified into two types. As a first type, after linearly-polarized light is incident to one end of the sensor fiber, a rotation angle of the polarization plane of the light output from the other end of the sensor fiber is measured. This is called a transmission type.

As a second type, after linearly-polarized light is incident to one end of the sensor fiber, a rotation angle of the polarization plane of the light reflected and returned at the other end of the sensor fiber (the light output from the incident end of the sensor fiber) is measured. This is called a reflection type.

These types will be described in brief with reference to FIGS. 3 and 4.

FIG. 3 schematically illustrates a configuration of the transmission type optical fiber electric current measurement apparatus in the related art (e.g., refer to Patent Document 1). Referring to FIG. 3, the transmission type optical fiber electric current measurement apparatus includes an optical polarizer 15, sensor fiber 11A, and an optical analyzer 16. The sensor fiber 11A is arranged to revolve around a conductive material 100 such as an electric cable through which the measurement current I, which is a target to be measured, flows. The optical polarizer 15 is installed in one end of the sensor fiber 11A, and the optical analyzer 16 is installed in the other end of the sensor fiber 11A.

In the transmission type optical fiber electric current measurement apparatus configured in this manner, the light from the light source 1 is incident to the optical polarizer 15 through an optical transmission fiber 71. The incident light is converted into linearly-polarized light of which vibration directions of electric fields are aligned in a single direction (a principal axis direction of the optical polarizer 15) by the optical polarizer 15 and then input to the sensor fiber 11A. In a revolving portion of the sensor fiber 11A, the linearly-polarized light propagating within the fiber is subjected to the Faraday effect due to the magnetic field generated around the measurement current I flowing through the conductive material 100. Thereby, the light is guided into the optical analyzer 16 while the polarization plane thereof is rotated by depending on the Faraday rotation angle proportional to the magnitude of the magnetic field. The output light from the sensor fiber 11A to the optical analyzer 16 is divided by the optical analyzer 16 into two polarization components of which polarization directions are perpendicular to each other (the principal axis direction of the optical analyzer 16 and its perpendicular direction), and each component is used as an optical detection signal. One of the divided light components is received by an optical receiver 13A via a signal transmission fiber 72A and converted into an electric signal S1. The other light component is received by an optical receiver 13B through a signal transmission fiber 72B and converted into an electric signal S2.

The amount of optical detection signal light received by each of the optical receivers 13A and 13B varies depending on the Faraday rotation angle applied to the linearly-polarized light propagating at the revolving portion of the sensor fiber 11A. The applied Faraday rotation angle can be obtained by processing electric signals S1 and S2 reflecting this variation using a signal processing circuit 141. The measurement current I is calculated based on the obtained Faraday rotation angle. In the example of FIG. 3, the signal processing unit 14 includes optical receivers 13A and 13B and a signal processing circuit 141, but they are not necessarily integrated into a single body.

In the transmission type optical fiber electric current measurement apparatus configured in this manner, the Faraday rotation angle in the sensor fiber 11A is denoted by θ_{F}. If the measurement current I=0, an angle between the polarization direction of the linearly-polarized light output from the sensor fiber 11A to the optical analyzer 16 and the principal axis direction of the optical analyzer 16 (i.e., the principal axis direction of the optical polarizer 15 and the principal axis direction of the optical analyzer 16) is denoted by θ₀. In this case, an optical bias setting is performed so as to obtain θ₀=π/4 (45°) by adjusting the angle θ₀ between the principal axis direction of the optical polarizer 15 and the principal axis direction of the optical analyzer 16.

It is known that the intensity Ps of the optical detection signal output from the optical analyzer 16 and received by the optical receivers 13A and 13B varies depending on cos(2θ₀-2θ_{F}). It is to be noted that an operation point when the Faraday rotation angle θ_{F} as a measurement amount is measured can be appropriately set by changing the angle θ₀ based on this formula. A process of changing and setting the angle θ₀ in order to determine this operation point is called an optical bias setting. An appropriate optical bias setting is very important to increase measurement accuracy. For example, in order to maximize a rate of change of the light intensity (i.e., detection sensitivity) given to the aforementioned formula when the Faraday rotation angle θ_{F} changes by a small amount, the angle θ₀ may be set to π/4. Therefore, in the optical fiber electric current measurement apparatus of FIG. 3, the angle between the principal axis directions of the optical polarizer 15 and the optical analyzer 16 is set to approximately θ₀=π/4)(45°).

FIG. 4 schematically illustrates a configuration of a reflection type optical fiber electric current measurement apparatus in the related art (e.g., refer to Patent Document 2).

Referring to FIG. 4, the reflection type optical fiber electric current measurement apparatus includes an optical circulator 19, a polarization splitter 18, a Faraday rotor 102, a sensor fiber 11B, and a reflector 111A. Similar to the transmission type, the sensor fiber 11B is arranged to revolve around a conductive material 100 such as an electric transmission cable through which the measurement current I, which is a target to be measured, flows. The Faraday rotor 102 is installed in one end of the sensor fiber 11B, and the reflector 111A is installed in the other end. Generally, the reflector 111A may be provided, for example, by depositing an electric multilayer film or a metal multilayer film on the cross-section of the sensor fiber 11B or by simply installing a mirror. Typically, the cross-section of the sensor fiber 11A to which the reflector 111A is attached is fabricated to have no or little polarization property in terms of reflectivity and transmissivity using a perpendicular polishing method or the like.

The Faraday rotor 102 and the polarization splitter 18 are interconnected with the optical fiber, and the polarization splitter 18 and the optical circulator 19 are interconnected with the optical fiber. The optical circulator 19 is arranged such that the light from the light source 1 is transmitted to the sensor fiber 11B side. Furthermore, the polarization splitter 18 and the Faraday rotor 102 are not connected by the optical fiber but may be integrated in a single body.

In the reflection type optical fiber electric current measurement apparatus configured in this manner, the light originated from the light source 1 is incident to the polarization splitter 18 via the optical transmission fiber 71 and the optical circulator 19. From this light, linearly-polarized light of which vibration directions of electric fields are aligned in a single direction (the principal axis direction of the polarization splitter 18) by the polarization splitter 18 is input to the Faraday rotor 102. The Faraday rotor 102 generates the Faraday rotation of approximately 22.5° in a single trip from the light traveling therethrough. As an example of a configuration of the Faraday rotor 102 for implementing this, FIG. 4 illustrates a case where the Faraday rotor 102 includes a permanent magnet 104 and a ferromagnetic garnet 103 having ferromagnetic crystals magnetically saturated by the permanent magnet 104. However, the Faraday rotor 102 may be implemented using any other configuration if it can provide the Faraday rotation of approximately 22.5° in a single trip. Depending on the wavelength of the light passing therethrough, other means may be used instead of the ferromagnetic garnet 103.

The linearly-polarized light passing through the Faraday rotor 102 is input to the sensor fiber 11B and is subjected to the Faraday effect due to the magnetic field generated around the measurement current I flowing through the conductive material 100 in the revolving portion of the sensor fiber 11B. The polarization plane of such linearly-polarized light is rotated depending on the Faraday rotation angle proportional to the magnitude of the magnetic field.

The light propagating through the sensor fiber 11B is reflected at the reflector 111A and travels through the revolving portion once again. In this case, it is necessary that the reflector 111A has high reflectivity so that there are no unnecessary losses in the signal intensity. The light passing through the revolving portion once again further receives the Faraday rotation due to the measurement current I flowing through the conductive material 100 and is output from the sensor fiber 11B to the Faraday rotor 102. The Faraday rotation of approximately 22.5° is further generated when the light passes through the Faraday rotor 102 once again. As a result, an optical bias of approximately 45° in a round trip is set by the Faraday rotor 102.

The light passing through the Faraday rotor 102 is guided again into the polarization splitter 18 and split into and output as two polarization components of which polarization directions are perpendicular to each other (i.e., the principal axis direction of the polarization splitter 18 and the direction perpendicular thereto). One of the components split by the polarization splitter 18 is received by the optical receiver 13A via the optical circulator 19 and the signal transmission fiber 72A and converted into an electric signal S1. Meanwhile, the other component is received by the optical receiver 13B via the signal transmission fiber 72B and converted into an electric signal S2.

Similar to the transmission type optical fiber electric current measurement apparatus, the amount of light (intensity) of each of the optical detection signals received by the optical receivers 13A and 13B varies depending on the Faraday rotation angle applied to the linearly-polarized light propagating through the revolving portion of the sensor fiber 11B. Therefore, the applied Faraday rotation angle can be obtained by processing the electric signals S1 and S2 reflecting this variation using the signal processing circuit 141. The measurement current I is calculated based on the obtained Faraday rotation angle. Even in this example, the signal processing unit 14 includes the optical receivers 13A and 13B and the signal processing circuit 141, but they may not be integrated into a single body.

A variety of signal processing methods may be employed in the signal processing unit 14. Whatever method is employed, it must obtain a desired measurement current I by executing a predetermined signal processing. For example, a modulation degree may be used for this purpose as disclosed in Patent Document 3. In this method, for example, each of the electric signals S1 and S2 is separated into DC (direct current) and AC (alternating current) components using a separation means included in the signal processing circuit 141, and these are standardized using a division means. As a result, it is possible to remove errors generated by imbalance of characteristics of the optical receivers 13A and 13B or errors generated by imbalance of the transmission path, to which each element is connected, such as the signal transmission fiber 72A and 72B, and thereby, increase measurement accuracy.

More specifically, the separation means includes a band pass filter (BPF) and a low pass filter (LPF). The AC components are separated by the BPF, and the DC components are separated by the LPF. Then, signal processing is performed to obtain a ratio between the DC and AC components using the division means. In this regard, the ratio between the AC and DC components is called a modulation degree. A process of obtaining the ratio between the AC and DC components is called standardization, and the output signal from the division means is called a modulation signal or a standardization signal. Each standardization signal based on the electric signals S1 and S2 is processed by an operator, and an output signal Sout of the measurement apparatus is obtained.

In this manner, a method of separating the output light from the sensor fiber 11A or 11B into two polarization components of which polarization directions are perpendicular to each other and obtaining measurement signal I flowing through the conductive material 100 using both of these optical detection signals is called a double-signal method.

By using the double-signal method, it is possible to remove errors caused by imbalance of characteristics of optical receivers included in each electric signal S1 and S2 or errors caused by fluctuation in a reference polarization orientation. Therefore, it is possible to obtain a high-accuracy optical fiber electric current measurement apparatus which is able to measure an electric current or magnetic fields. On the other hand, it is disadvantageous in that a large number of optical elements are required, and a circuit configuration or setup becomes complicated because it is necessary to adjust principal axis directions of mutual positions of these optical elements.

In this regard, as a different method from the double-signal method, a single-signal method has been proposed. In this method, two polarization components having perpendicular polarization directions are included in the output light from the sensor fiber 11A or 11B, and only one of them is used in the measurement. As a result, it is possible to reduce the number of optical elements and alleviate efforts to adjust them.

In this method, for example, any one of the optical detection signals passing through signal transmission fiber 72A in FIG. 3 or 4 or the optical detection signal passing through the signal transmission fiber 72B is used for the measurement. In comparison with the double-signal method, the optical fiber electric current measurement apparatus according to the single-signal method has the following disadvantages.

(i) In the transmission type optical fiber electric current measurement apparatus, since material may expand or contract depending on temperature, errors may be generated due to a force which deforms the sensor fiber 11A or 11B into a curve or a force which generates deformation or stress in material of the optical fiber.

(ii) In both transmission and reflection types of optical fiber electric current measurement apparatuses, errors may be generated in the measurement due to fluctuation in the luminescence state of the light source itself.

Hereinafter, the disadvantage (ii) will be described in more detail.

The noise caused by fluctuation in the luminescence state of the light source is considered as one of factors limiting the detection sensitivity of the optical fiber electric current measurement apparatus using the Faraday effect. According to studies in the related art, it is known that the light source has an optical amplifier mechanism based on stimulated emission such as a super luminescent diode (SLD) light source or an amplified spontaneous emission (ASE) light source using erbium-doped fiber, and it is advantageous to use a high-luminance and wide-band light source without installing a resonator or oscillating laser. Since such a light source has an optical wave front, it is possible to provide strong spatial coherence and introduce a sufficient amount of light into the optical fiber. Since such a light source has a wide spectrum width and weak temporal coherence, it is possible to prevent noise caused by the optical interference within an optical system.

Meanwhile, when such a light source is used, it is necessary to consider the following two factors due to fluctuation in the luminescence state which causes noise.

(A) Fluctuation in the luminescence intensity: the luminescence intensity may fluctuate due to a ripple in a power supply or the like.

(B) Fluctuation in the polarization state: the polarization state may fluctuate at random in a high speed (fundamental fluctuation caused by generation of photons and their random polarization states).

Focusing on the factor (A), the applicants have proposed a method of compensating for the fluctuation in the luminescence intensity (refer to Patent Document 4). This proposed method is shown in FIG. 5 and can be summarized as follows.

A part of the light guided from the light source 1 is extracted before being incident to the polarization splitter 18 included in an optical element 4 and used as an optical reference signal. The intensity Pr of this optical reference signal has an AC noise component overlapped on a constant DC component due to the fluctuation in the luminescence intensity (factor (A)) and the fluctuation in the polarization state (factor (B)) described above.

Meanwhile, the light except for the optical reference signal passes through the polarization splitter 18 included in the optical element 4 and is incident to the sensor fiber 11B. The light is linearly polarized after passing through the polarization splitter 18. However, due to the aforementioned factors (A) and (B), the intensity of the linear polarization fluctuates. This light is reflected at the reflector 111A installed in the other end of the sensor fiber 11B and travels in a round trip through the sensor fiber so that the polarization plane thereof is rotated by the Faraday effect caused by the magnetic field generated by the measurement current. As a result, the intensity of the light passing through the polarization splitter once again changes depending on the rotation angle of the polarization plane and functions as the optical detection signal having information on the measurement current.

The reference number 4 denotes an optical element including a polarization splitter 18 for linearly polarizing the light output from the light source 1 and a Faraday rotor 102 for setting the optical bias. The reference number 111A denotes a reflector. The optical element 4, the reflector 111A, and the sensor fiber 11B constitutes a so-called reflection type sensor head.

In the aforementioned configuration, the intensity of light which is guided from the light source 1 and passed through the polarization splitter 18 contains noise. Therefore, the intensity Ps of the optical detection signal passing through the signal transmission fiber 72B contains an AC noise component similar to the intensity Pr of the optical reference signal passing through the signal transmission fiber 72C in addition to a modulation component overlapped on a constant DC component due to the Faraday effect. The optical detection signal and the optical reference signal are guided to the optical receivers 13B and 13C as shown in the drawing and converted into electric signals S2 and R1, respectively. The electric signals S2 and R1 are separated into AC and DC components using BPFs 91A and 92A, LPFs 91B and 92B included in the separation means 91 and 92. Next, dividers 94A and 94B are used to obtain standardization signals Xs and Xr (more specifically, a standardization detection signal Xs and a standardization reference signal Xr). A value obtained by subtracting the standardization reference signal Xr obtained based on the electric signal R1 from the standardization detection signal Xs obtained based on the electric signal S2 using the subtractor 95 is output as the output signal Sout of the measurement apparatus. As a result, since the Faraday effect can be measured, it is possible to measure the measurement current flowing through the conductive material 100.

[Non-patent Document 1] “Investigation on Basic Characteristics of Optical Current Transducer Applying Optical Heterodyning Technique,” Institute of Electrical Engineers of Japan, Vol. 117-B, No. 3, pp 356-363, (1989)

[Patent Document 1] Japanese Patent No. 3415972

[Patent Document 2] Japanese Patent No. 3685906

[Patent Document 3] Japanese Patent No. 3300184

[Patent Document 4] PCT International Publication No. WO2006/095619

### DISCLOSURE OF INVENTION

### Problems to be Solved by the Invention

According to the configuration of FIG. 5, it is possible to compensate for the component caused by the fluctuation in the luminescence intensity of the factor (A) among noise components included in the detection signal due to the fluctuation in the luminescence state of the light source. However, it is still difficult to compensate for the component caused by the fluctuation in the polarization state of the factor (B) due to the following reasons.

Signals and components are defined as follows.

Xs: standardization detection signal

Ss: modulation signal component caused by the Faraday effect

N1s: noise component caused by the fluctuation in the luminescence intensity of the factor (A) included in Xs

N2s: noise component caused by the fluctuation in the polarization state of the factor (B) included in Xs

Xr: standardization reference signal

N1r: noise component caused by the fluctuation in the luminescence intensity of the factor (A) included in Xr

N2r: noise component caused by the fluctuation in the polarization state of the factor (B) included in Xr

Sout: output signal of the measurement apparatus

The following relationship is established between each signal and each component.

Xs=Ss+N1s+N2s (1a)

Xr=N1r+N2r (1b)

N1s=N1r (1c)

N2s≠N2r (1d)

Based on the equations (1a) to (1d), the following equation can be derived.

Sout=Ss+(N2s N2r) (2)

The reason of equations (1c) and (1d) is as follows.

(a) Reason of Equation N1s=N1r

It can be supposed that, if a ripple is generated in a power supply, the intensity of light emitted from the light source fluctuates in response to the ripple while the polarization degree does not change. Here, “the polarization degree does not change” means that, when the intensities of two perpendicular components in polarization are divided into a maximum component and a minimum component, a ratio between intensities of the two components and orientations thereof do not change. Therefore, considering that the light source has a wide spectrum width, a fluctuation rate of the intensity Pr (optical energy) of the polarization component of the light extracted as an optical reference signal from the light emitted from the light source is equal to a fluctuation rate of the intensity of the light incident to the sensor fiber after passing through the optical polarizer. Therefore, a fluctuation rate of the intensity Ps of the optical detection signal guided to the optical receiver 13B is equal to a fluctuation rate of the intensity Pr of the optical reference signal.

(b) Reason of Equation N2s≠N2r

Meanwhile, when a higher frequency is used as a detection target by reducing a time interval for signal analysis, photons are generated at random and accordingly polarized at random. Therefore, it is considered that the polarization state of the light originated from the light source fluctuates at random. Here, the “polarization state” includes a ratio of amplitude and a phase difference between both components when polarized light is divided into two perpendicular components. In this case, it is difficult to set a fluctuation rate of the intensity Ps of the optical detection signal guided to the optical receiver 13B so that it is equal to a fluctuation rate of the intensity Pr of the optical reference signal. This is because a polarization component of the light extracted as an optical reference signal from the light emitted from the light source is typically different from a polarization component of the light extracted as a detection signal using the optical polarizer.

In principle, it is not impossible to make polarization components extracted as the optical detection signal and the optical reference signal equal to each other. For example, this can be achieved by using a polarization plane maintaining fiber as a fiber used to guide the light from the light source to the optical polarizer and by accurately matching a principal axis orientation of the polarization plane maintaining fiber with an orientation of the optical polarizer and using a polarization plane maintaining coupler to extract the reference signal. However, it is difficult to accurately apply such a method to an industrial product in principle.

The present invention has been made to remove a noise component caused by fluctuation in the polarization state of the light source out of noise components in the aforementioned reflection type optical fiber electric current measurement apparatus using a simple method.

### Means for Solving the Problem

According to a first aspect of the present invention, there is provided a reflection type optical fiber electric current measurement apparatus to use a Faraday rotation effect for linearly-polarized light transmitted through the polarization splitter and incident to the sensor fiber, wherein an optical reference signal extractor is provided between the polarization splitter and the reflector provided in one end of the sensor fiber, and the optical reference signal extractor is used to separate a part of the linearly-polarized light and set it as the optical reference signal.

In this case, “between the polarization splitter and the reflector provided in one end of the sensor fiber” where the optical reference signal extractor is provided may include a polarization splitter and a reflector.

In the reflection type optical fiber electric current measurement apparatus, the reflector may be combined with the optical reference signal extractor. In addition, in order to combine the reflector with the optical reference signal extractor, the reflector may be constructed of a partial transmission mirror.

According to a second aspect of the present invention, there is provided a transmission type optical fiber electric current measurement apparatus to use a Faraday rotation effect for linearly-polarized light transmitted through the optical polarizer and incident to the sensor fiber, wherein an optical reference signal extractor is provided between the optical polarizer and the optical analyzer provided in one end of the sensor fiber, and the optical reference signal extractor separates a part of the linearly-polarized light to set it as an optical reference signal. In addition, “between the optical polarizer and the optical analyzer provided in one end of the sensor fiber” where the optical reference signal extractor is provided may include an optical polarizer and an optical analyzer

In the aforementioned reflection type and transmission type optical fiber electric current measurement apparatuses, the optical reference signal extractor may be constructed of a beam splitter. In addition, the optical reference signal extractor may be constructed of an optical coupler.

According to a third aspect of the present invention, there is provided a reflection type optical fiber electric current measurement method using a Faraday rotation effect for linearly-polarized light obtained by transmitting light through a polarization splitter, the method including: outputting light from a light source; transmitting the light through the polarization splitter and inputting the light to the sensor fiber; reflecting the light at a reflector provided in one end of the sensor fiber; setting the light again passing through the sensor fiber and through the polarization splitter as an optical detection signal; separating a part of the light that is transmitted through the polarization splitter and incident to the sensor fiber and arrives at the reflector provided in one end of the sensor fiber using an optical reference signal extractor provided between the polarization splitter and the reflector provided in one end of the sensor fiber (including the polarization splitter and the reflector) to use a part of the light as an optical reference signal; obtaining a standardization detection signal based on an electric signal obtained from the optical detection signal using an optical receiver; obtaining a standardization reference signal based on an electric signal obtained from the optical reference signal using an optical receiver; and detecting a measurement current by subtracting the standardization reference signal from the standardization detection signal.

According to a fourth aspect of the present invention, there is provided a transmission type optical fiber electric current measurement method using a Faraday rotation effect for linearly-polarized light obtained by transmitting light through an optical polarizer, the method including: outputting light from a light source; transmitting the light through the optical polarizer and inputting the light to the sensor fiber; setting the light passing through the optical analyzer provided in one end of the sensor fiber as an optical detection signal; separating a part of the light that is transmitted through the optical polarizer and incident to the sensor fiber before passing through the optical analyzer provided in one end of the sensor fiber using an optical reference signal extractor provided between the optical polarizer and the optical analyzer provided in one end of the sensor fiber (including the optical polarizer and the optical analyzer) to use a part of the light as an optical reference signal; obtaining a standardization detection signal based on an electric signal obtained from the optical detection signal using an optical receiver; obtaining a standardization reference signal based on an electric signal obtained from the optical reference signal using an optical receiver; and detecting a measurement current by subtracting the standardization reference signal from the standardization detection signal.

In the optical fiber electric current measurement method, any one of two polarization components of which polarization directions are perpendicular to each other out of the light passing through the sensor fiber and through the polarization splitter or the optical analyzer may be used as the optical detection signal.

### ADVANTAGE OF THE INVENTION

According to the present invention, in the optical fiber electric current measurement apparatus which detects the electric current by measuring the magnitude of the Faraday effect applied when the linearly-polarized light passing through the polarization splitter or the optical polarizer is incident to the sensor fiber and passed through the fiber, it is possible to remove noise components caused by fluctuation in the polarization state of the light source and further improve measurement accuracy by extracting a part of the linearly-polarized light and obtaining the optical reference signal.

### BRIEF DESCRIPTION OF THE DRAWINGS

FIG. 1 illustrates a configuration according to an embodiment of the invention.

FIG. 2 illustrates a configuration according to another embodiment of the invention.

FIG. 3 illustrates a configuration of a transmission type optical fiber electric current measurement apparatus in the related art using a double-signal method.

FIG. 4 illustrates a configuration of a reflection type optical fiber electric current measurement apparatus in the related art using a double-signal method.

FIG. 5 illustrates a configuration of a reflection type optical fiber electric current measurement apparatus in the related art using a single-signal method.

### DESCRIPTION OF THE REFERENCE SYMBOLS

1 . . . LIGHT SOURCE
2 . . . FIBER COUPLER
72A, 72B, AND 72C . . . SIGNAL TRANSMISSION FIBER
4 . . . OPTICAL ELEMENT
13A, 13B, AND 13C . . . OPTICAL RECEIVER
14 . . . SIGNAL PROCESSING UNIT
141 . . . SIGNAL PROCESSING CIRCUIT
15 . . . OPTICAL POLARIZER
16 . . . OPTICAL ANALYZER
18 . . . POLARIZATION SPLITTER
19 . . . OPTICAL CIRCULATOR
102 . . . FARADAY ROTOR
11 . . . SENSOR HEAD
11A AND 11B . . . SENSOR FIBER
111, 111A, AND 111B . . . REFLECTOR
100 . . . CONDUCTIVE MATERIAL
91 AND 92 . . . SEPARATION MEANS
91A AND 92A . . . BAND PASS FILTER (BPF)
91B AND 92B . . . LOW PASS FILTER (LPF)
94A AND 94B . . . DIVIDER
95 . . . SUBTRACTOR

### DETAILED DESCRIPTION OF THE PREFERRED EMBODIMENTS

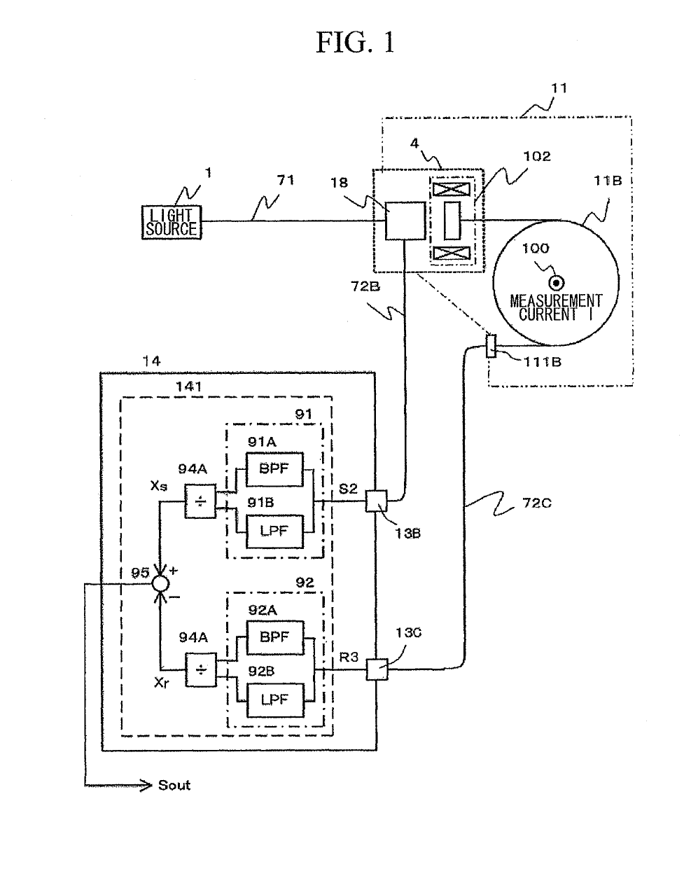

FIG. 1 illustrates an exemplary configuration according to an embodiment of the present invention, in which an electric current measurement apparatus using a reflection type optical current sensor device characterized in that a part of light output from a light source and transmitted through a polarization splitter is separated in an optical reference signal extractor provided between the polarization splitter and a reflector and is used as an optical reference signal.

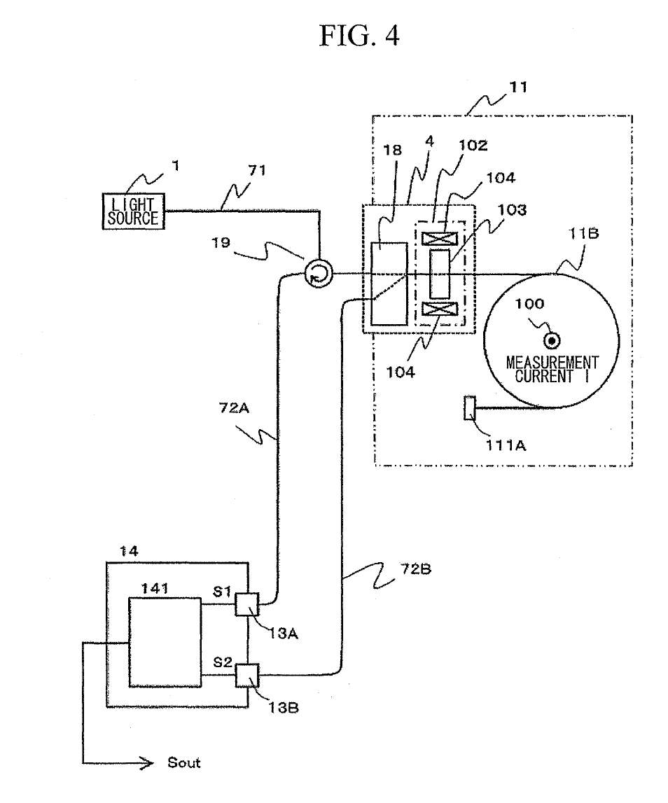

Referring to FIG. 1, an optical fiber electric current measurement apparatus according to an embodiment of the present invention includes a optical transmission fiber 71, signal transmission fiber 72B and 72C, an optical element 4 having a polarization splitter 18 and a Faraday rotor 102, and sensor fiber 11B. It is noted that the Faraday rotor 102 and the polarization splitter 18 are formed in an integrated structure optically connected as shown in FIG. 4. In addition, the Faraday rotor 102 and the polarization splitter 18 are not necessarily connected with optical fiber, but may be connected optically to each other. The sensor fiber 11B is arranged to revolve around (surround) a conductive material 100 such as an electric transmission cable through which the measurement current I, which is a target to be measured, flows. The Faraday rotor 102 is installed in one end of the sensor fiber 11B, and the reflector (mirror) 111B is formed in the other end. The polarization splitter 18 and the light source 1 are connected with the optical transmission fiber 71. The reflector 111B formed in one end of the sensor fiber 11B is implemented, for example, by depositing a dielectric multilayer film or a metal deposition film on a cross-section of the sensor fiber 11B. However, as show in FIG. 1, according to an embodiment of the present invention, the reflector 111B is combined with an optical reference signal extractor to have a different configuration from that of the reflector 111A of the reflection type optical fiber electric current measurement apparatus in the related art shown in FIG. 4. That is, in the reflection type optical fiber electric current measurement apparatus in the related art shown in FIG. 4, the reflector 111A has a total reflection mirror or a mirror capable of obtaining reflectivity close to the total reflection in order to minimize optical losses in the course of the reflection. Meanwhile, as shown in FIG. 1, in the present embodiment, it is necessary to combine the reflector 111B with an optical reference signal extractor to extract an optical reference signal using the reflector 111B. Therefore, in the present embodiment, a mirror (a partial transmission mirror) is employed for transmitting a part of the light arriving at the reflector 111B to the signal transmission fiber 72C. The partial transmission mirror is implemented by adjusting the thickness of the dielectric multilayer film or the metal deposition film (more specifically, the film thickness is made to be thinner than typical one). In addition, in the present embodiment, the signal transmission fiber 72C is connected to the reflector 111B having the partial transmission mirror. This configuration is also different from the reflection type optical fiber current mirror in the related art.

In the optical fiber electric current measurement apparatus configured in this manner, the light from the light source 1 is incident to the polarization splitter 18 included in the optical element 4 through the optical transmission fiber 71. Out of this light, a linearly-polarized light component of which vibration directions of electric fields are aligned in a single direction (the principal axis direction of the polarization splitter 18) by the polarization splitter 18 is input to the Faraday rotor 102. The Faraday rotor 102 applies a Faraday rotation angle of approximately 22.5° in a single trip to the light passing therethrough. The linearly-polarized light output from the Faraday rotor 102 is input to the sensor fiber 11B. In the revolving portion of the sensor fiber 11B, the linearly-polarized light receives the Faraday effect due to a magnetic field generated around the measurement current I flowing through the conductive material 100, and the polarization plane thereof is rotated depending on the Faraday rotation angle proportional to the magnitude of the magnetic field.

A part of the light propagating through the sensor fiber 11B is reflected at the reflector 111B. In the related art, the reflector 111B having higher reflectivity is selected in order to prevent unnecessary losses in the signal intensity. In the present embodiment, as shown in FIG. 1, a partial transmission mirror is used in the reflector 111B for partially transmitting the light as described above.

Similar to the related art, the light reflected at the reflector 111B passes through the revolving portion again. The light passing through the revolving portion is further subjected the Faraday effect by the measurement current I flowing through the conductive material 100 and then input to the Faraday rotor 102. Then, the light further receives a Faraday rotation angle of approximately 22.5° when passing through the Faraday rotor 102 again. Therefore, similar to the related art, an optical bias of approximately 45° is set by the Faraday rotor 102 in a round trip.

The light passing through the Faraday rotor 102 is guided to the polarization splitter 18 again and separated into two polarization components having polarization directions perpendicular to each other (a principal axis direction of the polarization splitter 18 and a direction perpendicular thereto). One part of the light separated by the polarization splitter 18 is received by the optical receiver 13B through the signal transmission fiber 72B and converted into an electric signal S2.

Meanwhile, the light transmitted at the reflector 111B without reflection is received by the optical receiver 13C via the signal transmission fiber 72C and converted into an electric signal R3. In other words, in the present embodiment, the reflector 111B is combined with the optical reflection signal extractor, and a part of the light is transmitted at the reflector 111B so that a part of the linearly-polarized light passing through the polarization splitter can be separated.

In the present embodiment, similar to the optical fiber electric current measurement apparatus in the related art, the amount of light received at the optical receiver 13B changes in response to the Faraday rotation angle applied to the linearly-polarized light propagating through fiber in the revolving portion of the sensor fiber 11B. The amount of light transmitted through the reflector 111B and received by the optical receiver 13C does not change in response to the Faraday rotation angle applied to the linearly-polarized light propagating through fiber in the revolving portion of the sensor fiber 11B.

The light transmitted through the reflector 111B also is subjected to the Faraday rotation, and the polarization plane of the linearly-polarized light fluctuates. However, the light transmitted through the reflector 111B does not pass through the optical element such as the optical polarizer or the optical analyzer. Therefore, in the present invention, the light beam aligned along a principal axis direction of such an optical element or the light beam perpendicular thereto is not extracted, but the intensity of the entire light including both the light beams are used. Therefore, the optical reference signal is independent on the optical detection signal, and the amount of light of the optical reference signal does not substantially change depending on the Faraday rotation.

As a result, it is possible to obtain the electric signal S2 using the optical receiver based on the intensity Ps of the optical detection signal which fluctuates in response to the current I flowing through the conductive material 100. In addition, it is possible to obtain the electric signal R3 using the optical receiver based on the intensity Pr of the optical reference signal which exists irrespective of the current I flowing through the conductive material 100.

The output signal Sout can be obtained by processing the electric signals S2 and R3 using the signal processing circuit 141 included in the signal processing unit 14. That is, the optical detection signal and the optical reference signal are guided by the optical elements 13B and 13C and converted into the electric signals S2 and R3, respectively. The electric signals S2 and R3 are separated into DC and AC components using the BPFs 91A and 92A and the LPFs 91B and 92B included in the separation means 91 and 92. Then, the standardization signals Xs and Xr (more specifically, the standardization detection signal Xs and the standardization reference signal Xr) are obtained using the dividers 94A and 94B. A value obtained by subtracting the standardization reference signal Xr obtained based on the electric signal R3 from the standardization detection signal Xs obtained based on the electric signal S2 using the divider 95 is output as the output signal Sout of the measurement apparatus. Therefore, it is possible to obtain the applied Faraday rotation angle and calculate the measurement current I based on the obtained Faraday rotation angle.

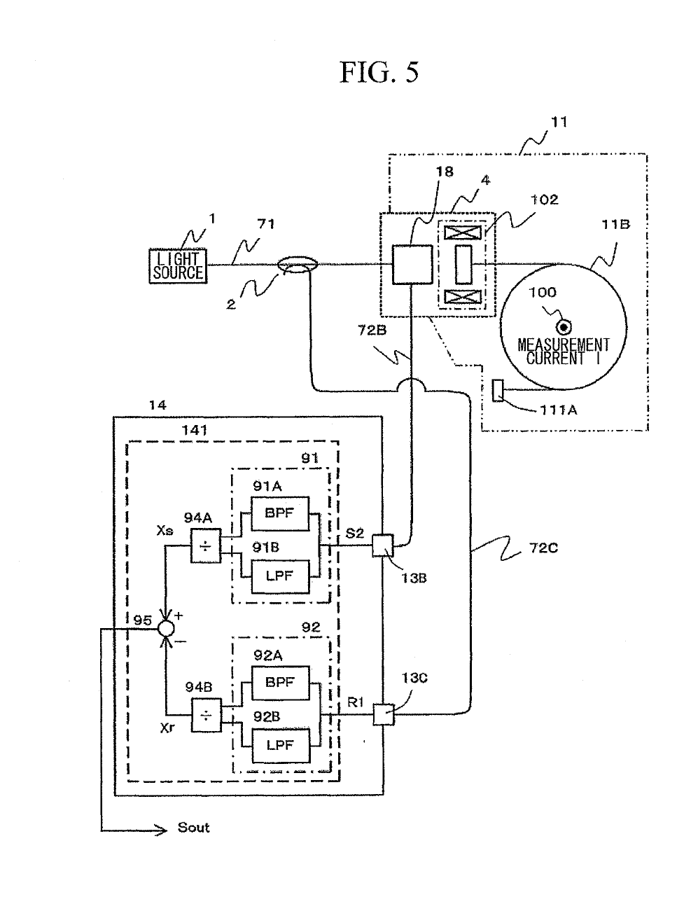

As is apparent from comparison with FIGS. 4 and 5, referring to FIG. 1, the reflector 111B which is able to partially transmit the incident light is provided in the leading end of the sensor fiber 11B, and the light transmitted through this reflector 111B is used as the reference signal to remove both the noise caused by the fluctuation in the luminescence intensity (A) included in the output signal and the noise caused by the fluctuation in the polarization state (B). While the measurement method using the reference signal and the signal processing method are similar to those described above, an embodiment of the present invention will be now be described focusing on differences from the related art.

Referring to FIG. 1, the intensity Pr of the optical reference signal transmitted through the reflector 111B and passing through the signal transmission fiber 72C is proportional to the intensity of the light passing through the polarization splitter 18 from the light source 1. Therefore, the noise component N2s, which is generated by the fluctuation in the polarization state included in the standardization detection signal Xs obtained based on the optical detection signal that is reflected at the reflector 111B and passed through the polarization splitter 18 once again, is substantially equal to the noise component N2r which is generated by the fluctuation in the polarization state included in the standardization reference signal Xr obtained based on the optical reference signal transmitted through the reflector 111B. The noise caused by the fluctuation in the polarization state is removed by subtracting the standardization reference signal Xr from the standardization detection signal Xs. Therefore, in the present embodiment, it is possible to compensate for the noise caused by the fluctuation in the polarization state (B) as well as the fluctuation in the luminescence intensity (A) described above.

More specifically, the aforementioned equation (1) can be transformed to the following equations (3a) to (3d).

Xs==Ss+N1s+N2s (3a)

Xr=N1r+N2r (3b)

N1s=N1r (3c)

N2s=N2r (3d)

The following equation (4) can be obtained by transforming the equations (3a) to (3d) into the equation (2).

Sout=Ss+(N2s−N2r)=Ss (4)

As a result, in the present embodiment, it is possible to remove the noise caused by the fluctuation in the polarization state (B) as well as compensate for the noise caused by the fluctuation in the luminescence intensity (A) of the light source.

In the example of the reflection type optical fiber electric current measurement apparatus shown in FIG. 1, the partial transmission mirror is used in the reflector 111B. The optical reference signal may be extracted using other methods if the light can be output to the sensor fiber 11B after passing through the polarization splitter 18, reflected at the reflector 111B, and then passed through the polarization splitter 18 again. That is, the present invention is not limited to the configuration in which the optical reference signal extractor is combined with the reflector 111B. For example, as a method of separating the light, a beam splitter or an optical coupler may be used. When the optical reference signal is extracted using other methods without separating the optical reference signal by transmitting a part of the light through the reflector 111B, a mirror generating less optical losses is preferably used in the reflector 111B similarly to that of the related art.

Hereinafter, operations of the optical fiber electric current measurement apparatus shown in FIG. 1 according to an embodiment of the invention will be described focusing on differences from the operations of the transmission type optical fiber electric current measurement apparatus in the related art.

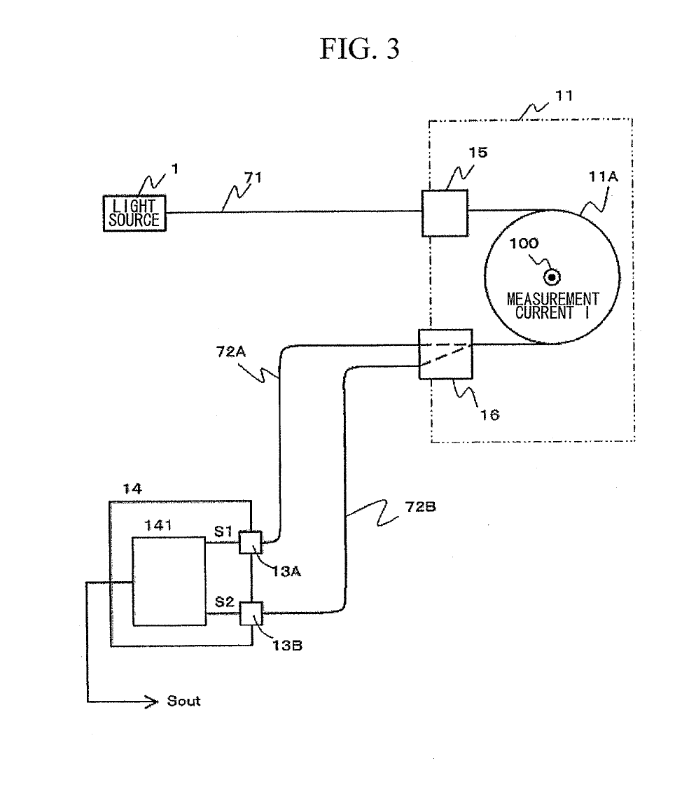

In the transmission type optical fiber electric current measurement apparatus in the related art shown in FIG. 3, the polarization state of the light which is transmitted through the sensor fiber and is subjected to the Faraday effect is measured using the optical analyzer. The optical analyzer is indispensable to measure fluctuation in the polarization plane of the linearly-polarized light obtained by passing through the optical polarizer, i.e., the Faraday rotation angle applied by the current I flowing through the conductive material 100. Meanwhile, in the present embodiment, the optical reference signal may have information on the light intensity of the linearly-polarized light, and the optical analyzer which is indispensable in the transmission type optical fiber electric current measurement apparatus of the related art can be unnecessary.

In the present embodiment, the light passing through the reflector 111B is delivered to the optical receiver 13C using the signal transmission fiber 72C without being incident to the optical analyzer and used as a monitor (i.e., a reference signal for removing noise) for monitoring the power of light which passes through the polarization splitter 18 and is incident to the sensor fiber 11B. The Faraday rotation angle generated within the sensor fiber depending on the current value flowing through the conductive material is detected by the polarization splitter 18 provided in the input stage of the sensor fiber 11B using the light (reflection light) reflected at the reflector 111B. Meanwhile, in the transmission type apparatus in the related art, the light passing through the optical analyzer 16 after the sensor fiber 11A is used to detect the Faraday rotation angle as an optical detection signal. Therefore, in the present embodiment, the light is transmitted through the reflector 111B for a purpose different from that of the transmission type apparatus in the related art. In the present embodiment, similar to the transmission type apparatus in the related art, it may be impossible to obtain the reflection light (optical detection signal) when the reflector 111B is not provided. That is, in the present embodiment, if the reflector 111B is removed, it may be impossible to detect the Faraday rotation angle generated within the sensor fiber depending on the current value flowing through a conductive material. In the present embodiment, since the optical analyzer is removed, it may not be possible to detect the Faraday rotation angle from the light (optical reference signal) transmitted through the reflector 111B. Therefore, the optical fiber electric current measurement apparatus in the present embodiment may not be able to achieve the function of the transmission type optical fiber electric current measurement apparatus.

Since the light passing through the sensor fiber is output from an end different from the input stage, the apparatus according to the present embodiment is similar to the transmission type apparatus in the related art. However, the apparatus according to the present embodiment is different from the transmission type apparatus in the related art in terms of the optical structures (such as whether or not the optical analyzer is provided) and the purpose of the light that passes through the sensor fiber and is output from the other end different from the input stage. It should be clearly noted that they are different.

Furthermore, in the transmission type apparatus in the related art, the output substantially depends on the curved shape of the sensor fiber in principle. In order to constantly maintain the contour of the curve, it may be necessary to fix the sensor fiber in a robust frame. Meanwhile, in the present embodiment, the polarization state of the light passing through the sensor fiber in a round trip is measured using the polarization splitter. Therefore, it is possible to achieve the advantage of the reflection type whereby the output of the light does not substantially depend on the curved shape of the sensor fiber. In the present embodiment, it is not necessary to fix the sensor fiber in a frame. It is possible to accurately measure the electric current just by winding the sensor fiber around the conductive material through which the measurement current flows. That is, since the optical fiber electric current measurement apparatus of the present embodiment has a small size in comparison with the transmission type apparatus in the related art, it is possible to make it flexible.

Next, the optical fiber electric current measurement apparatus of the present embodiment shown in FIG. 1 will be compared with the reflection type optical fiber electric current measurement apparatus in the related art. Advantageously, the apparatus of FIG. 1 can remove the noise caused by the fluctuation in the polarization state (B) that cannot be sufficiently removed using the optical fiber electric current measurement apparatus in the related art. This is implemented by separating a part of the linearly-polarized light which passes through the polarization splitter used in the measurement of the Faraday rotation angle and is incident to the sensor fiber 11B by the optical reference signal extractor and using it as a monitor (a reference signal for removing noise) for monitoring the power of light. In this regard, the apparatus of FIG. 1 is different from the reflection type apparatus in the related art. As a structural difference, the apparatus in the related art employs the reflector 111A having high reflectivity in order to reduce signal losses while the apparatus of FIG. 1 employs the reflector 111B through which a part of light passes. In the present embodiment, the configuration for separating and extracting a part of the linearly-polarized light using the optical reference signal extractor contributes to removing the noise caused by the fluctuation in the polarization state (B) of the light source as well as the fluctuation in the luminescence intensity (A) of the light source.

In addition, in a case where the reflector shown in FIG. 1 is combined with the optical reference signal extractor to separate the optical reference signal using the reflector 111B, “a partial transmission mirror” is necessarily provided in one end of the sensor fiber, and a function thereof cannot be achieved using the total reflection mirror provided in the related art.

As described above, in the present embodiment, a part of the linearly-polarized light that passes through the polarization splitter or the optical polarizer and is incident to the sensor fiber is separated using the optical reference signal extractor, and the separated light is used as the optical reference signal. As a result, in the present embodiment, it is possible to remove the noise caused by the fluctuation in the polarization state (B) of the light source that cannot be removed by the apparatus in the related art.

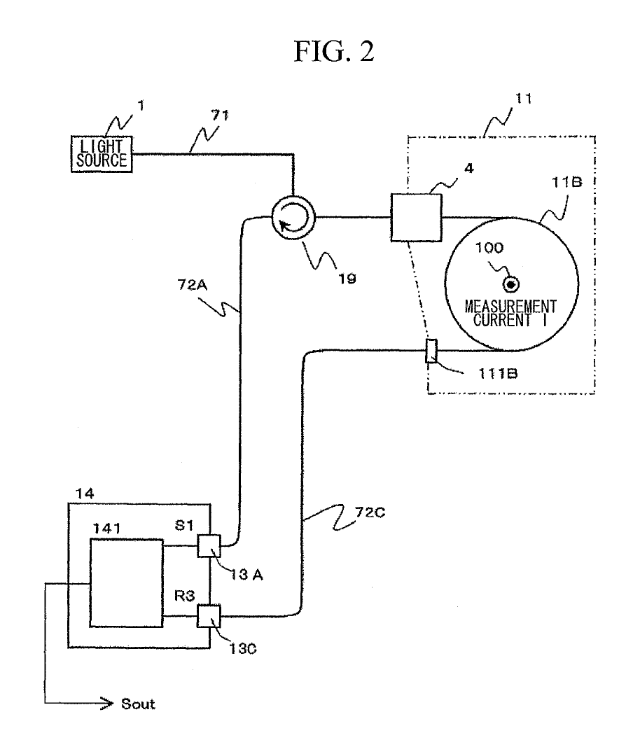

In addition, as a method of extracting the optical detection signal, a configuration shown in FIG. 2 can be employed. FIG. 2 illustrates a modified example of FIG. 1. The configuration of FIG. 2 is different in that the optical circulator 10 is used to extract the optical detection signal unlike the configuration of FIG. 1. In FIG. 2, other elements are substantially the same as those of FIG. 1, and descriptions thereof will be omitted. In FIG. 2, the fluctuation in the intensity of the linearly-polarized light aligned in a principal axis direction of the polarization splitter 18 is used in detection. In other words, the linearly-polarized light of the optical detection signal of FIG. 2 is perpendicular to the linearly-polarized light of the optical detection signal of FIG. 1. Other elements such as the light source 1, the optical transmission fiber 71, the optical circulator 19, the polarization splitter 18, and the signal transmission fiber 72A are similar to those of the reflection type optical fiber electric current measurement apparatus in the related art in the connection state or the light transmission state, and description thereof will be omitted. Generally, it is possible to use an optical fiber coupler instead of the optical circulator.

In both FIGS. 1 and 2, the reflector 111B is combined with the optical reference signal extractor. However, the present invention is not limited to an example in which the optical reference signal is extracted using the reflector 111B. A part of the light that passes through the polarization splitter 18 and is directed to the reflector 111B may be separated in the middle of a path between the polarization splitter 18 and the reflector 111E and used as the optical reference signal. Otherwise, a part of the light reflected at the reflector 111B and directed to the polarization splitter 18 once again may be separated in the middle of a path between the reflector 111B and the polarization splitter 18 and used as the optical reference signal.

Although not shown in the drawing, the optical reference signal extractor may employ a variety of different configurations. As an example of using other elements than the reflector 111B as the optical reference signal extractor, the optical reference signal extractor may be constructed using a beam splitter or an optical coupler. Even in this case, it is possible to separate a part of the light passing through the polarization splitter 18. The beam splitter may be provided in any location if the linearly-polarized light can be separated. The beam splitter is preferably provided in a location before the light is subjected to the Faraday effect caused by the measurement current to make it easier to set the optical axis. For example, the beam splitter is preferably provided near the polarization splitter or the Faraday rotor. The optical coupler may also be provided in any location. Considering the effect of the measurement current, it is preferable that the optical coupler be provided near the reflector or the polarization splitter. When the beam splitter or the optical coupler is employed in the optical reference signal extractor, and the reflector is not used as the optical reference signal extractor, the reflector 111B is preferably configured using a mirror having high reflectivity similar to the apparatus in the related art to reduce optical losses.

In the aforementioned embodiments and modified examples thereof, a reflection type optical fiber electric current measurement apparatus is used. According to another embodiment, a transmission type optical fiber electric current measurement apparatus may be used. For example, in the transmission type apparatus in the related art in FIG. 3, a reference signal extractor may be added between the optical polarizer 15 and the detector 16. In this case, before the light is output from the optical analyzer 16 after the light passes through the optical polarizer 15, a part of the light is separated (extracted) at the optical reference signal extractor. By using this extracted light as the optical reference signal, it is possible to remove the noise caused by the fluctuation in the polarization state (B) as well as the fluctuation in the luminescence intensity (A) of the light source. Even in this case, a variety of configurations may be applied to the optical reference signal extractor. For example, a beam splitter or an optical coupler may be used as the optical reference signal extractor.

When the measurement current I has a high frequency, a difference in the time elapsed until each of the optical detection signal and the optical reference signal arrives at the optical receiver often generates a measurement error. Therefore, it is preferable that the length of the signal transmission fiber be adjusted such that the difference in the arriving time can be within an allowable range considering the frequency.

1. A reflection type optical fiber electric current measurement apparatus including a polarization splitter, a sensor fiber, and a reflector to use a Faraday rotation effect for linearly-polarized light transmitted through the polarization splitter and incident to the sensor fiber, the apparatus comprising:
an optical reference signal extractor provided between the polarization splitter and the reflector provided in one end of the sensor fiber,
wherein the optical reference signal extractor separates a part of the linearly-polarized light to set the part of the light as the optical reference signal.

2. The reflection type optical fiber electric current measurement apparatus according to claim 1, wherein the reflector is also used as the optical reference signal extractor.

3. The reflection type optical fiber electric current measurement apparatus according to claim 1 or 2, wherein the reflector is a partial transmission mirror.

4. A transmission type optical fiber electric current measurement apparatus including an optical polarizer, a sensor fiber, and an optical analyzer to use a Faraday rotation effect for linearly-polarized light transmitted through the optical polarizer and incident to the sensor fiber, the apparatus comprising:
an optical reference signal extractor provided between the optical polarizer and the optical analyzer provided in one end of the sensor fiber,
wherein the optical reference signal extractor separates a part of the linearly-polarized light to set the part of the light as an optical reference signal.

5. The optical fiber electric current measurement apparatus according to any one of claims 1 to 4, wherein the optical reference signal extractor is a beam splitter.

6. The optical fiber electric current measurement apparatus according to any one of claims 1 to 4, wherein the optical reference signal extractor is an optical coupler.

7. A reflection type optical fiber electric current measurement method using a Faraday rotation effect for linearly-polarized light obtained by transmitting light through a polarization splitter, the method comprising:
outputting light from a light source;
transmitting the light through the polarization splitter and inputting the light to the sensor fiber;
reflecting the light at a reflector provided in one end of the sensor fiber;
setting the light passing through the sensor fiber once again and through the polarization splitter as an optical detection signal;
separating a part of the linearly-polarized light using an optical reference signal extractor provided between the polarization splitter and the reflector provided in one end of the sensor fiber to use a part of the light as an optical reference signal;
obtaining a standardization detection signal based on an electric signal obtained from the optical detection signal using an optical receiver;
obtaining a standardization reference signal based on an electric signal obtained from the optical reference signal using an optical receiver; and
detecting a measurement current by subtracting the standardization reference signal from the standardization detection signal.

8. A transmission type optical fiber electric current measurement method using a Faraday rotation effect for linearly-polarized light obtained by transmitting light through an optical polarizer, the method comprising:
outputting light from a light source;
transmitting the light through the optical polarizer and inputting the light to the sensor fiber;
setting the light passing through the optical analyzer provided in one end of the sensor fiber as an optical detection signal;
separating a part of the linearly-polarized light using an optical reference signal extractor provided between the optical polarizer and the optical analyzer provided in one end of the sensor fiber to use a part of the light as an optical reference signal;
obtaining a standardization detection signal based on an electric signal obtained from the optical detection signal using an optical receiver;
obtaining a standardization reference signal based on an electric signal obtained from the optical reference signal using an optical receiver; and
detecting a measurement current by subtracting the standardization reference signal from the standardization detection signal.

9. The optical fiber electric current measurement method according to claim 7 or 8, wherein the optical detection signal is any one of two polarization components of which polarization directions are perpendicular to each other.
